(19) United States
(12) Patent Application Publication
(10) Pub. No.: US 2006/0221566 A1
(43) Pub. Date: Oct. 5, 2006

(54) Apparatus and method for variably configuring computer component assemblages, and resultant computer

(76) Inventor: Hursh V. Prasad, Bethesda, MD (US)

Correspondence Address: KRAMER LEVIN NAFTALIS & FRANKEL LLP;INTELLECTUAL PROPERTY DEPARTMENT, 1177 AVENUE OF THE AMERICAS, NEW YORK, NY, 10036, US

(21) Appl. No.: 11/245,702

(22) Filed: Oct. 6, 2005

Related U.S. Application Data
(60) Provisional application No. 60/667,039, filed on Apr. 1, 2005.

(51) Int. Cl. G06F 1/16; H05K 5/00

(52) U.S. Cl. 361/683; 361/679; 312/223.1; 312/223.2

(57) ABSTRACT

The housing of computer components in a range of differently configured computer shells via a support structure adapted for fixable positioning within any and all of said shells, which support structure is further adapted for attachment thereto of such computer components or further adapted for supporting one or more additional elements, at least one of which elements is adapted for attachment thereto of such computer components; a computer comprising said support structure; and methods of providing such support, or producing such computer.

### FIELD OF THE INVENTION

The invention relates to computers of variegated configuration and technology concerning standardized support structure for mounting computer components within any of a range of differently configured external shells.

### BACKGROUND OF THE INVENTION

Personal computers are typically factory-assembled and contain components that are fixed within a metal casing using screws, bolts, etc. Thus, a desktop computer usually comprises an external shell in the nature of a rectangular metal box that can either rest horizontally or stand in a vertical tower configuration. Some computer manufacturers have offered differently shaped shells, but a computer's internals cannot be easily rearranged; therefore, component arrangements for one shell design cannot readily be used for a different shell design. Individuals who assemble computers on their own must find a component mounting system that is compatible with the external shell at hand, and then components that are compatible with a particular mounting system. Custom design efforts are complicated by this factor.

One approach heretofore suggested is to insert disk drives into a metal frame designed for mounting such that its main axis runs either vertically or horizontally within the primary computer frame. This gives the builder flexibility to orient disk drives in one of two basic configurations. See U.S. Pat. No. 5,513,068.

Another approach has been to adapt a metal frame to accommodate both disk drives and expansion cards. The frame may then be mounted within the primary computer frame. By accommodating two kinds of hardware, components can be varied over the lifetime of the computer without completely taking the computer apart. See U.S. Pat. No. 6,058,007.

Still another approach to custom computer design has been to affix grooved covers to the sides of a computer frame, so that the computer may be engaged to a rack, where it can be stored alongside other computers. See U.S. Pat. No. 6,201,702.

However, these techniques are inadequate to provide a solution for the need to have a versatile technology permitting the mounting of computer components utilizing standardized parts in a variety of differently configured computer shells. It would be beneficial to have mounting technology that would enable the flexible positioning of components in a wide range of configurations. It would be also be advantageous if the mounting system could be easily installed and removed, allowing the computer designer to swap components without using screws or hand tools.

### OBJECTS OF THE INVENTION

It is an object of the invention to provide a system, apparatus and method for convenient mounting of computer components in a wide variety of differing computer shell configurations.

It is another object of the invention to provide a system, apparatus and method for the convenient and economical production of a wide range of differently shaped computers.

### SUMMARY OF THE INVENTION

In one aspect, the invention is an apparatus for mounting computer components within any of a plurality of differently configured external shells for housing computer components. The apparatus comprises: a support structure adapted for fixable positioning within each and every one of a plurality of differently configured external shells; said structure being further adapted for attachment thereto of said computer components, or further adapted for supporting one or more additional elements, at least one of which elements is adapted for attachment thereto of said computer components. As an additional feature, the apparatus can include one or more brackets incorporated in the apparatus which alternatively permit the attachment to a surface (other than a computer shell) such as a desk top or the like.

In a further aspect, the invention is a computer which comprises: an external shell of a given configuration; a support structure which is adapted for fixable positioning within any of a plurality of differently configured external shells, and which is fixed in position within said external shell of given configuration; which support structure is further adapted for attachment thereto of computer components, or for supporting one or more additional elements at least one of which elements is adapted for attachment thereto of said computer components; an assemblage of computer components attached to said structure or at least one of said additional elements.

In another aspect, the invention is a method for providing support for computer components within any of a plurality of differently configured external shells for housing said computer components, which method comprises: interiorly fixing to said any of a plurality of differently configured external shells a support structure adapted for fixable positioning within each and every one of said differently configured external shells; and further adapted for attachment thereto of said computer components, or for supporting one or more additional elements, at least one of which elements is adapted for attachment thereto of said computer components.

In yet another aspect, the invention is a method for assembling a computer having any of a plurality of differently configured external shells, the method comprising: interiorly fixing to said any of a plurality of differently configured shells a support structure adapted for fixable positioning within each and every one of said differently configured external shells; and attaching computer components to said support structure.

Practice of the invention confers significant advantages. Because the support structure for a computer's internal components is adapted for securing within a range of differently configured external shells, the invention provides a level of versatility heretofore unavailable in commercial operations. A single, universal support structure design can be adopted for use with a wide spectrum of varying shells, to yield significant production efficiencies and economies. Additionally, the invention affords a high degree of design flexibility. Moreover, it permits computer owners to change the external appearance of their units with comparative ease, since the internal computer components and support structure therefor can be disengaged from one shell and inserted into another having a different “look” without the need to substitute new parts specifically for the shell having the different “look”. The following discussion will elucidate the manner in which these and other advantages are realized.

### BRIEF DESCRIPTION OF THE DRAWINGS

FIG. 1A is a perspective view (not to scale) of apparatus in accordance with the invention showing among other things an assembled chassis within a receptacle, located within a computer shell (depicted in dashed lines for the sake of clarity) and a separately-positioned platform also located within the shell.

FIG. 1B is a plan view (not to scale) of the bottom of the aforementioned computer shell.

FIG. 2 is an exploded view (not to scale) of apparatus in accordance with the invention as depicted in FIG. 1A, showing among other things support structure for computer components as aforesaid.

FIG. 3 is an enlarged perspective view (not to scale) of a platform for mounting computer components.

### DESCRIPTION OF CERTAIN PREFFERED EMBODIMENTS

A central feature of the invention is the interchangeability, among a wide range of differently configured external shells, of the structure for supporting a computer's internal components. This feature is referred to herein as “swapability”. Such swapability is achieved in the case of this invention by providing the support structure with a plurality of attachment elements, at least some of which are in register with corresponding attachment elements within each of the differently configured shells, whereby a capability of universal mounting within any of a variety of external shells is achieved. Each of the shells is in turn equipped with one or more attachment elements that (so to speak) line up with one or more of the attachment elements provided in or on the support structure. In this manner, the support structure can be fastened to any of a variety of external shells. Moreover, as mentioned above, the support structure can also incorporate one or more brackets (or the like) which serve as points of attachment for the apparatus to a desk top or other surface, rather than within a computer shell, which provides yet an additional degree of versatility.

In certain embodiments of the invention, a further flexibility results from the utilization of multiple platforms—i.e., the base platform and one or more additional platforms—on which to mount computer components. The platforms can be mounted one on another, with the base platform being attached to support structure fastened to the external shell. Alternatively, one or more of the additional platforms can be fastened to the external shell independently of the main support structure. For instance, in a shell which is longer than it is wide, the base platform (either bearing one or more additional platforms, or not) can be mounted to the shell at the latter's rear, and one or more further platforms attached separately to the shell more toward its front.

The swapability feature of the present invention is a significant advance over, and distinguishes the invention from, current commercial technology in which each shell configuration requires its own specialized support structure, involving at least a customized fastening arrangement to mate with the design of the shell. The further flexibility conferred by utilization of one or more additional platforms, mounted on a base platform or independently fastened to the external shell, is another feature not found in various products currently commercially available. Thus, the invention is superior to the aforementioned current commercial technology/products because unlike the latter it does not require a different array of custom designed support structure and/or specially shaped components for one external shell as opposed to another.

The support structure utilized in accordance with the invention typically comprises struts, rails or other comparable members adapted for fastening to the external shell, (to which members is mounted (directly or indirectly) a base platform for accommodating one or more additional platforms, computer components, and optionally computer hardware. As previously indicated, the base platform can be attached to the aforementioned members directly, or indirectly through one or more intermediate elements. For example, the intermediate elements can be members which are fixed (detachably if desired) to the members attached to the external shell, or can be rails which slide back and forth along the members attached to the shell (in which latter case the members attached to the shell can also be rails which engage with the intermediate rails). In various good embodiments of the invention a chassis, such as box-shaped receptacle or a frame, is attached to the aforementioned intermediate struts, rails, etc.; the base platform is fixed or otherwise fitted in or on the chassis. The chassis can be held in place via one or more locking mechanisms. The members attached to the external shell, the intermediate members and the chassis are typically fashioned of any suitable light, durable, manipulable material such as aluminum or plastic (for instance, acrylic polymer).

The aforementioned members and chassis are fastened to each other (or in the case of certain of the members to the external shell as described above) through the use of nuts and bolts or screws inserted through ports or holes in the members and chassis (and the external shell in certain embodiments), by means of plastic snaps, or via other conventional attachment technology. The sites on the support structure which are provided for attachment to one or another of the range of external shells contemplated herein are referred to as “shell attachment sites”.

The “swapability” feature of the invention is achieved through coordinating the location of one or more of the shell attachment sites on the support structure with the site(s) provided for that purpose on every one of the shells in the contemplated range as aforesaid. For instance, a support structure in accordance with the invention can have ten shell attachment sites in total. For a group of five differently configured external shells with which the support structure is adapted to be compatible, the location(s) of one or more (though not necessarily all) shell attachment sites on the support structure is (are) pre-positioned to be in register with or otherwise correspond to the location(s) of the one or more attachment sites on each of the external shells in the aforementioned group. It will be understood that the one or more shell attachment sites actually in register with any particular external shell can change from one shell to another, depending on the number and location of the attachment sites as those parameters vary from one external shell to another. Swapability is enhanced in certain good embodiments of the invention wherein the support structure and the fasteners by which it is attached to the external shell are adapted such that the support structure can be readily removed after fixation to the shell.

As also mentioned previously, one or more platforms other than the base platform are advantageously utilized in certain good embodiments of the invention. The use of such platforms increases the capacity for housing of computer components, computer hardware, etc. And, because one or more of these extra platforms can be “piggybacked” on the base platform, or one on another for that matter (with at least one of the additional platforms being mounted to the base platform), as well as being mounted independently at other locations by direct fastening to the external shell, an additional increase in the adaptivity to external shell configuration provided by the invention is realized. These extra platforms are typically formed of conventional materials and attached to the base platform, one another, or the external shell utilizing the same attachment technology as described previously for attachment of the support structure to the external shell.

As will be understood, the invention finds application in the loading within any suitable external shell of all manner of electronics and other equipment items (including without limitation hardware) necessary and/or advantageous to the operation of a computer. The items referred to encompass: various circuit boards; power supplies; cooling fans; connectors for coupling to peripheral devices such as monitors, keyboards, printers, etc.; storage devices such as floppy disk drives, hard disk drives, tape drives, CD-ROM drives; brackets or housings into which storage devices can be inserted; and power switches. The term “computer components” as used herein shall mean all such electronics and other equipment items mentioned above.

In certain good embodiments of the invention, when such computer components are mounted on a base platform associated with the support structure as aforesaid—or on the base platform and one or more additional platforms “piggybacked” (directly or indirectly) on the base platform as discussed above—the support structure is capable of manipulation to move the base platform (and any platforms mounted directly or indirectly thereto) from the position it normally occupied during operation of the computer to a position in which computer components attached thereto are more readily accessed, such that said computer components can be accessed all at once. By way of example, if the platform(s) is (are) supported by a chassis, the movement of the chassis from within the shell (for instance, by sliding it along mounting rails as mentioned herein away from the internal position it would ordinarily occupy during operation of the computer) can be accomplished so as to translate the platform(s) and any attached computer components all at once to a position more readily accessible for purposes of examination, component replacement, or the like.

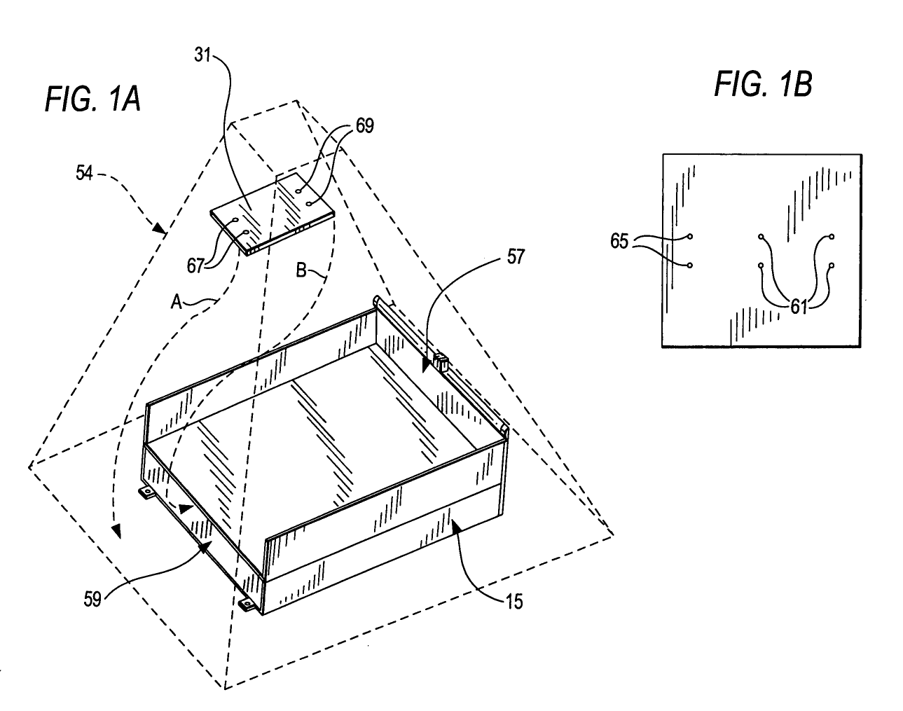

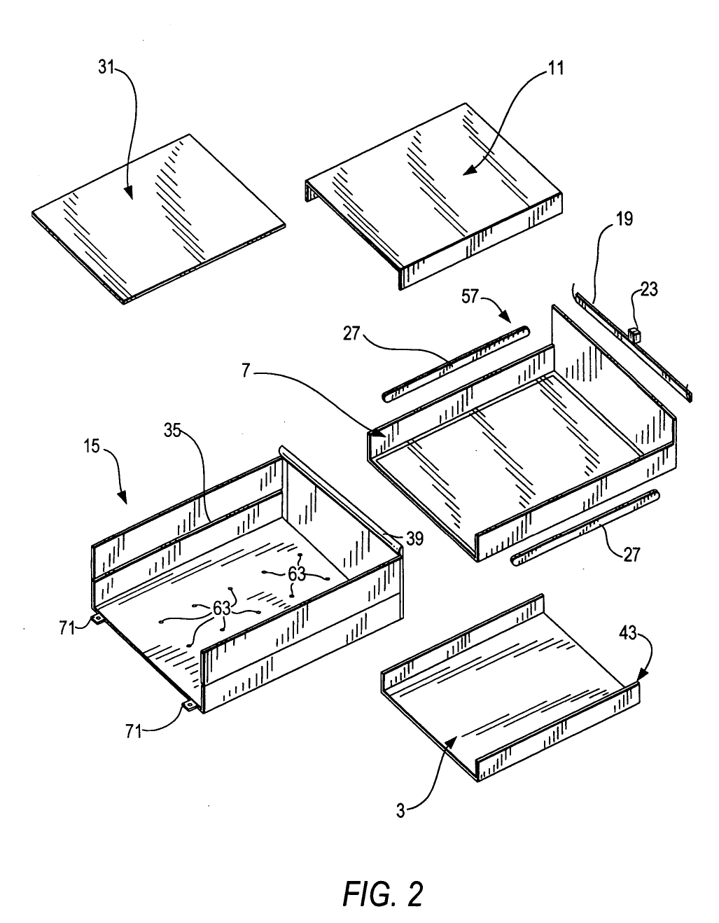

With reference to FIGS. 1A, 1B and 2, support structure 59 as discussed above comprises chassis 57 mounted within receptacle 15, a box adapted to accommodate chassis 57. The chassis itself comprises rectangular frame 7 with attachment points for multiple trays. Rails 27 can be attached the sides of the chassis to allow it to slide into a receptacle. Latch system 19 serves to fix the chassis to the receptacle, and latch release button 23 permits removal of the chassis from the receptacle. The receptacle is fixed to the interior of external shell 54, and serves to secure the chassis in a desired position. While external shell 54 as shown has a truncated pyramidal shape, it can alternatively be of any size or shape capable of accommodating the physical dimensions of the desired computer components and support elements therefore, including chassis receptacle 15. The shell has interior attachment points 61 (FIG. 1B) that allow mounting of the chassis receptacle via attachment at four corresponding shell attachment sites 63 in receptacle 15; receptacle 15 is also equipped with brackets 71 (those on the opposite side of the receptacle cannot be seen) for the purpose of alternatively mounting the support structure on a desk top or other surface. A further component tray 31 can be mounted separately either to shell 54 by attachment at sites 65 and 67 (as indicated via dashed line A), or to tray 3 by attachment at sites 69 and 47 (as indicated via dashed line B). This allows positioning of computer components at different locations within the shell, for example, positioning of a tray (and disk drive mounted thereto) near the front of a shell, with the receptacle, chassis, and other components near the rear.

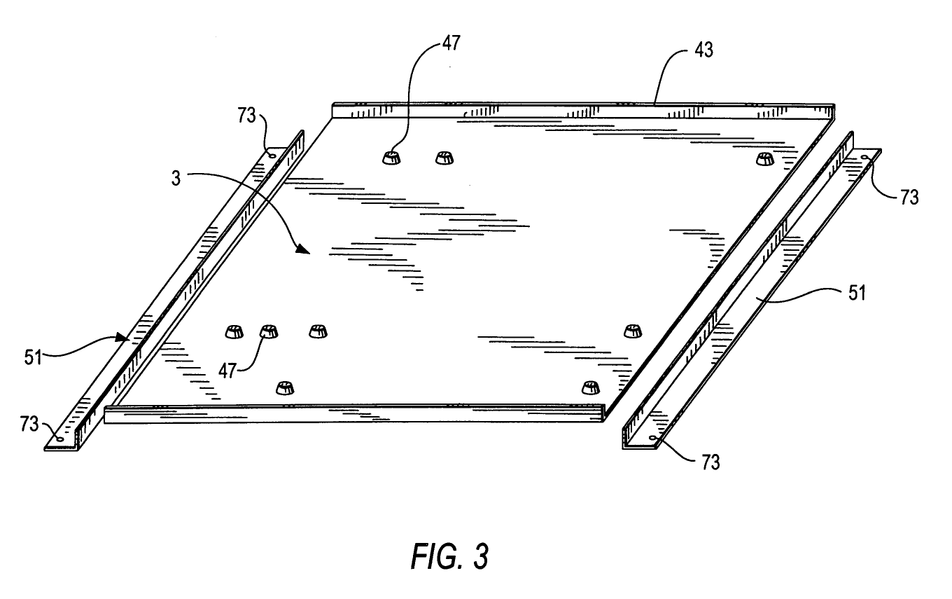

In FIGS. 2 and 3 more detailed depictions of various features, including platforms 3, 11 and 31, are provided; each of such platforms is adapted for mounting thereto of computer components including without limitation motherboards, disk drives, batteries, cooling fans, and power switches. The base platform is tray 3 which in the embodiment shown in FIG. 1 is positioned within chassis 57. Tray 3 is fashioned of a suitable metal or alloy, includes raised sides 43, and (as shown in FIG. 3) has threaded screw holes 47 for attachment of computer components to the tray. To allow attachment of the widest range of commercially available motherboards, the tray features screw holes spaced according to industry standard motherboard form factors such as ATX, BTX, and VIA ITX. The motherboard screw hole apertures are raised several millimeters above the surface of the tray to allowing clearance space for any protruding motherboard components. The tray can optionally be fitted with side brackets 51 (shown in FIG. 3, but not FIG. 2 for the sake of simplicity) having screw holes 71 to allow direct attachment to external surfaces. The foregoing applies to platforms 11 and 31 also, except that such platforms differ from base platform 3 in that they are mounted to another platform or to the external shell itself rather than being positioned within chassis 57.

In accordance with the foregoing, tray 31 for holding computer components is mounted individually to external shell 54, as in FIG. 3.

The invention described herein is susceptible of many modifications and variations within its scope, and in particular extends to the use of any one or more of the singular and several features of the foregoing description and accompanying drawings and their equivalents.

What is claimed is:

1. Apparatus for mounting computer components with any of a plurality of different external shells for housing computer components within a computer, the apparatus comprising a support structure adapted for fixable positioning within each and every one of a plurality of differently configured external shells, and further adapted for attachment thereto of said computer components, or for supporting one or more additional elements, at least one of which elements is adapted for attachment thereto of said computer components.

2. The apparatus as defined in claim 1, in which said one or more additional elements comprises a base platform adapted for attachment thereto of computer components.

3. The apparatus as defined in claim 2, in which said one or more additional elements further comprises at least one further platform mounted on said base platform, said at least one further platform adapted for attachment thereto of computer components.

4. The apparatus as defined in claim 2, wherein said support structure is capable of manipulation to move the base platform from the position it normally occupies during operation of said computer to a position in which computer components attached thereto are more readily accessed, such that said computer components can be accessed all at once.

5. The apparatus as defined in claim 1, which further comprises brackets incorporated in said support structure and adapted for attachment to a surface other than the interior of said external shells.

6. The apparatus as defined in claim 1, wherein said support structure and the fasteners by which it is attached to the shell are adapted such that the support structure can be readily removed after said fixation.

7. Apparatus for supporting computer components within any of a plurality of differently configured external shells for housing said computer components, the apparatus comprising:
a receptacle which is adapted for fixable positioning within each and every one of said plurality of differently configured external shells;
a chassis adapted for supporting a platform for said computer components, which chassis is mounted to the receptacle;
a platform adapted for supporting computer components attached to the chassis and adapted for supporting computer components.

8. The apparatus as defined in claim 7, which further comprises one or more rails attached to the chassis and one or more rails attached to said receptacle, such that said rails interengage to permit the chassis to slide in and out of the receptacle.

9. The apparatus as defined in claim 7, wherein said chassis is secured to said receptacle by a locking mechanism.

10. The apparatus as defined in claim 7, in which said support structure and the fasteners by which it is attached to the shell are adapted such that the support structure can be readily removed after said fixation.

11. A computer which comprises:
an external shell of a given configuration;
a support structure which is adapted for fixable positioning within any of a plurality of differently configured external shells, and which is fixed in position within said external shell of given configuration, which support structure is further adapted for attachment thereto of computer components, or for supporting one or more additional elements at least one of which elements is adapted for attachment thereto of said computer components;
an assemblage of computer components attached to said structure or at least one of said additional elements.

12. The computer as defined in claim 11, in which said one or more additional elements comprises a base platform adapted for attachment thereto of computer components.

13. The computer as defined in claim 12, in which said one or more additional elements further comprises at least one additional platform mounted on said base platform, said at least one additional platform adapted for attachment thereto of computer components.

14. The computer as defined in claim 12, wherein said support structure is capable of manipulation to move the base platform from the position it normally occupies during operation of said computer to a position in which computer components attached thereto are more readily accessed, such that said computer components can be accessed all at once.

15. The computer as defined in claim 11, in which said support structure is adapted such that it can be readily removed after it can be readily removed after said fixation.

16. A computer which comprises:
an external shell of a given configuration;
a receptacle which is adapted for housing computer components within each and every one of a plurality of differently configured external shells, and which is fixed in position within said external shell of given configuration;
a chassis adapted for supporting a platform for said computer components, which chassis is mounted to the receptacle;
a platform adapted for attachment thereto of computer components attached to the chassis and adapted for attachment thereto of computer components; an assemblage of computer components attached to said platform.

17. The computer as defined in claim 16, in which one or more rails attached to the chassis and one or more rails attached to said receptacle, such that said rails interengage to permit the chassis to slide in and out of the receptacle.

18. The computer as defined in claim 16, in which said chassis is secured to said receptacle by a locking mechanism.

19. The computer as defined in claim 16, in which said support structure is adapted such that it can be readily removed after it can be readily removed after said fixation.

20. A method of providing support for computer components within any of a plurality of differently configured external shells for housing said computer components, which method comprises interiorly fixing to said any of a plurality of differently configured external shells a support structure adapted for fixable positioning within each and every one of said differently configured external shells, and further adapted for attachment thereto of said computer components, or for supporting one or more additional elements, at least one of which elements is adapted for attachment thereto of said computer components.

21. The method as defined in claim 20, in which said one or more additional elements comprises a base platform adapted for attachment thereto of computer components.

22. The method as defined in claim 21, in which said one or more additional elements further comprises at least one additional platform mounted on said base platform, said at least one additional platform adapted for attachment thereto of computer components.

23. The method as defined in claim 20, wherein said support structure is adapted such that it can be readily removed after it can be readily removed after said fixation.

24. A method of providing support for computer components within any of a plurality of differently configured external shells for housing said computer components, which method comprises:
interiorly fixing to said any of a plurality of differently configured shells a support structure including a receptacle which is adapted for fixable positioning within each and every one of said differently configured external shells, which receptacle is further adapted for mounting thereto a chassis adapted for supporting a platform for said computer components.

25. The method as defined in claim 24, wherein one or more rails attached to the chassis and one or more rails attached to said receptacle, such that said rails interengage to permit the chassis to slide in and out of the receptacle.

26. The method as defined in claim 24, wherein said chassis is secured to said receptacle by a locking mechanism.

27. The method as defined in claim 24, wherein said support structure is adapted such that it can be readily removed after it can be readily removed after said fixation.

28. A method of assembling a computer having any of a plurality of differently configured external shells, which method comprises:
interiorly fixing to said any of a plurality of differently configured shells a support structure adapted for fixable positioning within each and every one of said differently configured external shells, and attaching computer components to said support structure.

29. The method as defined in claim 28, wherein said one or more additional elements comprises a base platform adapted for attachment thereto of computer components.

30. The method as defined in claim 29, wherein said one or more additional elements further comprises at least one additional platform mounted on said base platform, said at least one additional platform adapted for attachment thereto of computer components.

31. The method as defined in claim 28, wherein said support structure is adapted such that it can be readily removed after it can be readily removed after said fixation.

32. A method of assembling a computer having any of a plurality of differently configured external shells, which method comprises:
interiorly fixing to said any of a plurality of differently configured shells a support structure including a chassis receptacle which is adapted for fixable positioning within each and every one of said differently configured external shells, which receptacle is adapted for mounting thereto of a chassis adapted for supporting a platform for said computer components, and attaching computer components to said support structure.

33. The method as defined in claim 32, wherein one or more rails attached to the chassis and one or more rails attached to said receptacle, such that said rails interengage to permit the chassis to slide in and out of the receptacle.

34. The method as defined in claim 33, wherein said chassis is secured to said receptacle by a locking mechanism.

35. The method as defined in claim 32, wherein said support structure is adapted such that it can be readily removed after it can be readily removed after said fixation.
